(19) United States
(12) Patent Application Publication
(10) Pub. No.: US 2021/0147220 A1
(43) Pub. Date: May 20, 2021

(54) STICTION-AIDED FABRICATION OF FLAT NANOMEMBRANES FOR MICROELECTRONICS APPLICATIONS

(71) Applicants: WiSys Technology Foundation, Inc., Madison, WI (US); Wisconsin Alumni Research Foundation, Madison, WI (US)

(72) Inventors: Gokul Gopalakrishnan, Platteville, WI (US); Paul Gregory Evans, Madison, WI (US)

(21) Appl. No.: 17/046,918

(22) PCT Filed: Apr. 11, 2019
(86) PCT No.: PCT/US19/26870

§ 371 Date: Oct. 12, 2020

Related U.S. Application Data
(60) Provisional application No. 62/655,944, filed on Apr. 11, 2018.

(51) Int. Cl. B81C 1/00; B81B 3/00

(52) U.S. Cl. CPC B81C 1/00158; B81C 2201/0169; B81B 3/0021

(57) ABSTRACT

Methods for forming stable, suspended nanomembranes are provided. Also provided are stable, suspended nanomembranes made using the methods and electronic devices that incorporate the stable, suspended nanomembranes as electronically active layers. The methods utilize stiction-aided nanomembrane flattening combined with ultraviolet (UV) radiation-induced adhesion enhancement.

### CROSS-REFERENCE TO RELATED APPLICATIONS

The present application claims priority to U.S. provisional patent application No. 62/655,944 that was filed Apr. 11, 2018, the entire contents of which are hereby incorporated herein by reference.

### BACKGROUND

Semiconductor nanomembranes are sheets of single-crystal semiconductor materials, such as silicon, less than a few hundred nanometers thick, with areas that can exceed thousands of square micrometers, including areas in the range from 10 μm² to 10 million μm². These nanomembranes can be formed by partially or completely releasing the top single-crystalline semiconductor device layer of a semiconductor-on-insulator wafer.

Freestanding silicon nanomembranes have applications in electronic and photonic materials, micromechanical devices, x-ray optics, macromolecular filters, lithographic templates, as sensors, and as low-absorption and environmental chamber windows for optical, x-ray, and electron microscopy. All of these applications benefit from flat crystalline structures with low lateral inhomogeneity. Ultra-thin freestanding membranes with nanometer-scale flatness, however, have been difficult to fabricate. More commonly, a buckling pattern is observed in nanomembranes fabricated from semiconductor-on-insulator wafers.

### SUMMARY

Methods for forming stable, suspended semiconductor nanomembranes are provided. Also provided are stable, suspended semiconductor nanomembranes made using the methods and electronic devices, such as microelectromechanical systems (MEMS) devices, that incorporate the stable, suspended semiconductor nanomembranes. The semiconductor nanomembranes are thin films of single-crystalline semiconductor that can be formed from the device layer of a semiconductor-on-insulator wafer.

One embodiment of a method of forming a stable, flattened membrane begins with a structure that includes a sacrificial material layer disposed between a substrate and a membrane layer. The method includes the steps of removing the substrate below a portion of the membrane layer; etching away the sacrificial material layer below the portion of the membrane layer, such that the portion of the membrane layer is suspended over an opening in the sacrificial layer and the substrate, wherein the etching undercuts the membrane layer to form a ledge on the substrate; forming a film of water on a lower surface of the suspended portion of the membrane layer; allowing the film of water to dry, whereby regions of the membrane layer become bonded to the ledge on the substrate via stiction; and increasing the bonding strength between the membrane layer and the substrate.

Increasing the bonding strength between the membrane layer and the substrate can be accomplished by irradiating the bonded regions of the membrane layer with ultraviolet (UV) radiation and annealing the membrane layer and the substrate at an elevated temperature. The resulting increased bonding strength is the equal to or greater than the intrinsic breaking strength of the membrane layer.

In some embodiments of the methods, the structure is a semiconductor-on-insulator structure comprising a single-crystalline semiconductor device layer as the membrane layer, a buried oxide layer as the sacrificial material layer, and a handle wafer as the substrate.

One embodiment of a semiconductor-on-insulator wafer structure that includes a stable, suspended semiconductor nanomembrane comprises: a handle wafer substrate, a single-crystal semiconductor device layer, and a buried oxide layer disposed between the handle wafer substrate and the single-crystal semiconductor device layer. In the structure, a portion of the single-crystal semiconductor device layer is suspended over an opening in the buried oxide layer and the handle wafer substrate, and a region of the single-crystal semiconductor device layer around the suspended portion is bonded to a ledge on the handle wafer substrate with an adhesion strength that is equal to or greater than the intrinsic breaking strength of the single-crystal semiconductor device layer.

One embodiment of a structure that can be made using the methods described herein includes: a substrate; a membrane layer; and a sacrificial material layer disposed between the substrate and the membrane layer; wherein a portion of the membrane layer is suspended over an opening in the sacrificial material layer and the substrate, and further wherein a region of the membrane layer around the suspended portion is bonded to a ledge on the substrate with an adhesion strength that is equal to or greater than the intrinsic breaking strength of the membrane layer.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIG. 1 is a schematic diagram showing a processing scheme for the formation of a suspended, buckled single-crystal semiconductor nanomembrane from a semiconductor-on-insulator substrate.

FIG. 2 is a schematic diagram showing a processing scheme for the stiction-aided flattening of a suspended single-crystal semiconductor nanomembrane.

FIG. 3 is a schematic diagram showing a processing scheme for increasing the adhesion between a flattened, suspended single-crystal semiconductor nanomembrane and a support substrate.

FIG. 4A is a top view of a nanomembrane-based piezoresistive MEMS pressure sensor with strain gauge elements patterned into the membrane by doping with electrically active impurities. FIG. 4B is a side view of the pressure sensor.

### DETAILED DESCRIPTION

Methods for forming stable, suspended nanomembranes are provided. Also provided are stable, suspended nanomembranes made using the methods and electronic devices, such as MEMS devices, that incorporate the stable, suspended nanomembranes as electronically active layers.

The methods can begin with a structure that includes a sacrificial material layer disposed between a substrate and a membrane layer. In the description that follows, the methods are illustrated using semiconductor-on-insulator structures as the beginning structures. However, is should be understood that other substrates, sacrificial material layers, and membrane layers can be used.

The methods begin with the formation of a nanomembrane in an elastically metastable configuration that is subsequently stabilized by additional processing. For example, in some embodiments of the methods the stabilization is achieved by exposure to ultraviolet radiation and thermal annealing. The semiconductor nanomembranes are thin films of a semiconductor material, typically having a thickness of no greater than 1 μm. For example, various embodiments of the semiconductor nanomembranes have thicknesses in the range from about 5 nm to about 500 nm. The nanomembranes can have large lateral diameters. For example, the width dimensions of a semiconductor nanomembrane can exceed 100 μm, 200 μm, or 500 μm.

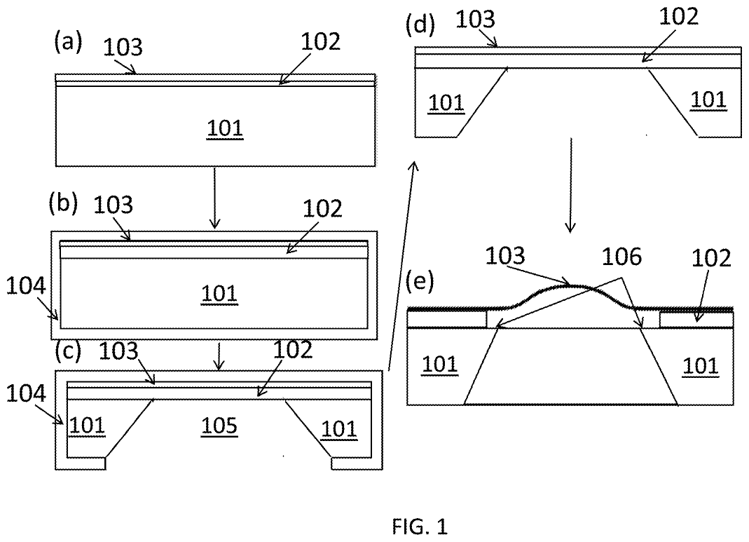

In an initial step of the method, a suspended semiconductor nanomembrane that is supported only along one or more edges is formed in a metastable state using a stiction-aided flattening process, as described in Gopalakrishnan et al., Appl. Phys. Lett. 102, 033113 (2013), the entire disclosure of which is incorporated herein for the purpose of describing a method for forming a suspended semiconductor nanomembrane in a metastable state. A schematic diagram showing the stiction-aided flattening process is shown in FIG. 1, panels (a)-(e). Briefly, the stiction-aided flattening process begins with a semiconductor-on-insulator (SOI) substrate that includes a semiconductor handle wafer 101, a thin buried oxide (BOX) layer 102 on the surface of the semiconductor handle wafer, and a single-crystalline semiconductor device layer 103 on the surface of the BOX layer 102 (FIG. 1, panel (a)). In some embodiments of the SOI, the handle wafer 101 is a silicon wafer, the BOX layer is a layer of silicon dioxide, and the semiconductor device layer 103 is a layer of single-crystalline silicon. An initial step in the process involves removing the semiconductor handle wafer and the BOX below a portion of the semiconductor device layer. This can be accomplished, for example, by lithographically patterning and sequentially etching away those layers. By way of illustration, a silicon handle wafer can be selectively etched by coating the structure in a silicon nitride etch mask 104 using, for example, low pressure chemical vapor deposition (LPCVD) (FIG. 1, panel (b)), followed by an anisotropic backside etch through handle wafer 101 with potassium hydroxide (KOH) (FIG. 1, panel (c)). Optionally, the semiconductor device layer can be thinned by a sequence of thermal oxidation and selective etching, prior to deposition of the silicon nitride coating. BOX layer 102 can act as an etch stop for the backside handle wafer etch. Etch mask 104 can then be removed (FIG. 1, panel (d)). For example, a silicon nitride mask can be removed using H₃PO₄ at elevated temperatures (e.g., ˜160° C.). Next, BOX layer 102 can be selectively removed below semiconductor device layer 103, resulting in a released and suspended semiconductor nanomembrane that is supported along its edges by the remaining BOX 102 and handle wafer 101 (FIG. 1, panel (e)). A silicon dioxide BOX can be etched using, for example, HF. The etch of the BOX is allowed to continue until semiconductor device layer 103 is undercut and a ledge 106 is formed on the surface of handle wafer 101 around the opening in handle wafer 101 (FIG. 1, panel (e)). Once released, nanomembrane 103 buckles due to residual stress.

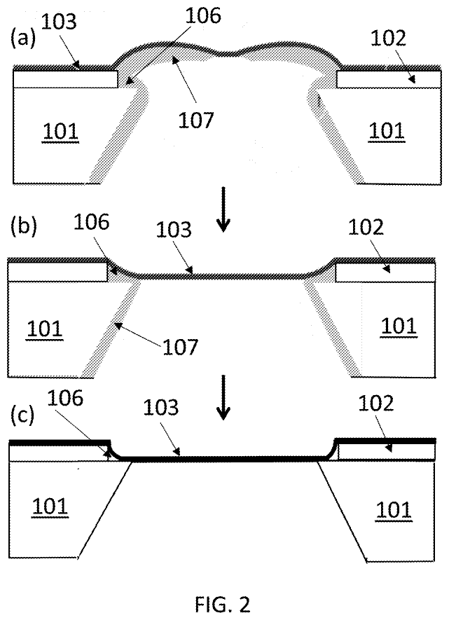

A flattening process provides the capability to easily produce flat nanomembranes beyond the buckling threshold. FIG. 2, panels (a)-(c), is a schematic diagram showing the process of flattening the resulting released portion of the nanomembrane. In this process, the BOX etching and undercut can be stopped by deionized water or an aqueous solution, resulting in the formation of a film of water 107 on the backside of buckled nanomembrane 103 (FIG. 2, panel (a)). As the water dries, the trailing edge of the water film progresses outward from the center of the nanomembrane as the water evaporates (FIG. 2, panel (b)). Once the nanomembrane is completely dry (FIG. 2, panel (c)), it is stretched out, and buckling is confined to the region around ledge 106, adjacent to BOX 102. The resulting stiction-flattened semiconductor nanomembrane is bonded to the supporting microfabricated ledge 106 by weak adhesion forces and is thus in a temporary, metastable state. In this state, the adhesion strength is lower than the intrinsic breaking strength of the nanomembrane, and delamination of the nanomembrane from the supporting handle wafer can occur. The time-period required for the delamination can range from minutes to months and can dramatically limit the usefulness of membranes that are flattened but not stabilized through additional processing.

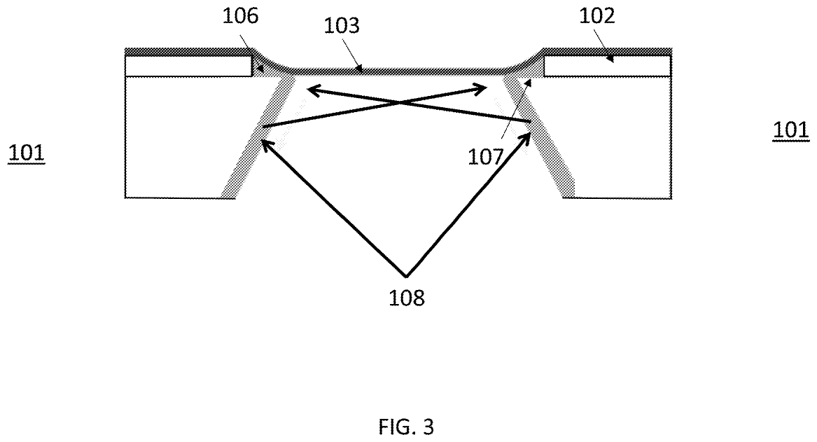

An adhesion enhancement process is carried out in order to form a permanent bond between nanomembrane 103 and the support ledge formed on the surface of handle wafer 101. The adhesion stabilization process described here involves two steps: (i) UV activation, followed by (ii) moderate temperature thermal treatment in a dry air environment, for example, an environment having a water content of 10 ppm or lower. UV activation can be achieved by exposing the single-crystal semiconductor nanomembrane to UV radiation 108 in a standard UV or UV-ozone chamber (FIG. 3). By way of illustration, the semiconductor nanomembrane can be exposed to 254 nm UV radiation at room temperature (˜23° C.) or elevated temperatures up to 100° C., for about 15 minutes. Typical times for the UV exposure are in the range from 3 to 30 minutes, generally varying inversely with the temperature, although exposure times outside of this range can be used.

Bonding processes other than, or in addition to, the UV and heating process described here can also be used to provide additional routes for permanent adhesion. For example, adhesive coatings or intermediate layers can be provided between the substrate and the membrane. By way of illustration, an oxide layer can be grown by wet or dry thermal oxidation at more elevated temperatures (typically between 800° C. and 1200° C.), with or without the UV activation process, which can be used to add a thicker bonding layer in the interfacial region between the membrane 103 and the supporting ledge 106. This process also converts several nm of the top and bottom surfaces of the membrane 103 into silicon dioxide. These silicon dioxide layers can be removed by an HF etch, if needed, resulting in a reduction of the membrane thickness. Alternatively, a thin film deposited conformally across the bottom of the membrane 103 and the side walls of the handle wafer cavity 101 can be used to keep the membrane flat. Such a process reduces the flexibility and transparency of the membrane, which hinders certain applications.

Alternatively, again optionally in addition to the UV and heating process, areas of enhanced adhesion can be created by depositing materials in the region between the membrane 103 and the supporting ledge 106 using atomic layer deposition or another conformal coating method involving the delivery of gaseous or liquid precursors. Growth of an oxide layer by wet or dry thermal oxidation at more elevated temperatures (typically above 700° C.), with or without a UV activation process, can be used to add a thicker bonding layer in the interfacial region between the membrane 103 and the supporting ledge 106.

The UV activation takes advantage of the high planarity of the side-walls produced during anisotropic etching of the single-crystal silicon handle wafer. These side-walls are oriented at an angle of approximately 54.7° (e.g., ˜54°-55°) from the horizontal plane, permitting a suitably low angle of entry for the UV radiation into the water gap separating the membrane bottom surface and the top of the undercut ledge, when the sample is positioned appropriately with respect to the UV source. A second feature that makes this method particularly advantageous for silicon nanomembranes is the relatively high reflectivity of silicon in the specific range of UV wavelengths that promote the cleavage of water molecules in the remaining water film and produce the hydroxyl linkages that give rise to strong bonding between surfaces. UV activation for silicon can be performed using a standard mercury vapor lamp that produces primarily 254 nm and 185 nm wavelengths, in which range the reflectivity of silicon varies from about 0.6 to 0.8. Finally, the semiconductor nanomembrane can be thermally annealed at an elevated temperature (e.g., a temperature in the range from 250° C. to 450° C., including temperatures in the range from 300° C. to 400° C.). Typical annealing times are in the range from 5 to 16 hours, although annealing times outside of this range can be used.

The suspended single-crystal semiconductor nanomembrane is bonded to the handle wafer with an adhesion strength that is greater than the intrinsic breaking strength of the nanomembrane. This property can be tested by subjecting the suspended semiconductor nanomembrane to increasing pressures. If the nanomembrane breaks before it delaminates from the substrate, its adhesion strength is greater than its intrinsic breaking strength. By way of illustration only, some embodiments of flattened silicon nanomembranes made using the present methods can withstand a pressure of at least 30 psi without delaminating from the substrate. However, the breaking strength for a given membrane will depend, at least in part, on its thickness. Various embodiments of the flattened semiconductor nanomembranes have thicknesses in the range from about 5 nm to about 300 nm. However, nanomembranes having thicknesses outside of this range can also be formed.

The adhesion enhancement process is especially useful when bonding is required between difficult to access surfaces in electronic devices, such as MEMS devices, the vast majority of which are fabricated from single-crystal silicon. Such surfaces cannot be activated by standard plasma techniques that are commonly applied to full wafers. In addition to expanding the types of surfaces that can be activated for subsequent thermal bonding, the present process effectively turns stiction, which has traditionally been considered a hindrance in MEMS manufacture, into a new fabrication tool.

These membranes provide a technology platform for smaller and more sensitive MEMS devices. These devices include high-sensitivity, low-footprint pressure sensors enabled by the thinness of the membrane. Additional applications can be found in: lab-on-chip devices for macromolecular separation, manipulation, and sensing; pressure chambers and fluid wells for microfluidic devices; low-absorption sample mounts for microscopy; and environmental chamber windows for electron, x-ray, and optical microscopy. Other devices and applications into which the semiconductor nanomembranes can be incorporated include molecular sieves, photonic and phononic devices, and shadow masks.

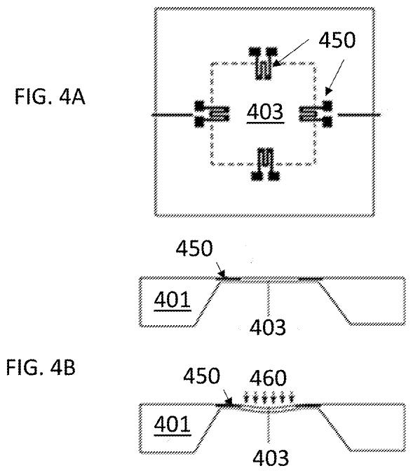

One embodiment of a MEMS pressure sensor into which a flattened semiconductor nanomembrane has been incorporated can be made by incorporating one or more piezoresistive strain gauges into a suspended and flattened silicon nanomembrane along one or more of its edges. One such pressure sensor is shown schematically in FIG. 4A (top view) and FIG. 4B (cross-sectional side view). The pressure sensor includes four strain gauges 450 overlapping the semiconductor nanomembrane 403 which is suspended over an opening in a sacrificial layer (not shown due to scale) and handle layer 401. When a differential pressure 460 is applied to the upper surface of semiconductor nanomembrane 403, piezoresistive strain gauges 450 are configured such that they are placed under tensile stress, which is registered by the sensor through a bridge circuit.

Although single-crystal silicon nanomembranes are examples of flattened nanomembranes that can be formed using the present methods, the methods can be used to form single-crystal nanomembranes of other closely related semiconductor materials, such as germanium and silicon-germanium.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A method of forming a stable, flattened membrane from a structure comprising a sacrificial material layer disposed between a substrate and a membrane layer, the method comprising:
removing the substrate below a portion of the membrane layer;
etching away the sacrificial material layer below the portion of the membrane layer, such that the portion of the membrane layer is suspended over an opening in the sacrificial layer and the substrate, wherein the etching undercuts the membrane layer to form a ledge on the substrate;
forming a film of water on a lower surface of the suspended portion of the membrane layer;
allowing the film of water to dry, whereby regions of the membrane layer become bonded to the ledge on the substrate via stiction; and
increasing the bonding strength between the membrane layer and the substrate.

2. The method of claim 1, wherein increasing the bonding strength between the membrane layer and the substrate comprises:
irradiating the bonded regions of the membrane layer with ultraviolet radiation; and
annealing the membrane layer and the substrate at an elevated temperature, wherein the increased bonding strength is equal to or greater than an intrinsic strength of the membrane layer.

3. The method of claim 1, wherein the structure is a semiconductor-on-insulator structure comprising a single-crystalline semiconductor device layer as the membrane layer, a buried oxide layer as the sacrificial material layer, and a handle wafer as the substrate.

4. The method of claim 3, wherein the single-crystalline semiconductor device layer comprises single-crystalline silicon and the handle wafer is a silicon wafer.

5. The method of claim 4, wherein increasing the bonding strength between the membrane layer and the substrate comprises:
irradiating the bonded regions of the single-crystalline silicon layer with ultraviolet radiation; and
annealing the single-crystalline silicon layer and the handle wafer at an elevated temperature, wherein the increased bonding strength is equal to or greater than an intrinsic strength of the single-crystalline silicon layer.

6. The method of claim 1, wherein the membrane layer has a thickness in the range from 5 nm to 300 nm.

7. The method of claim 1, wherein the elevated temperature is in the range from 250° C. to 450° C.

8. The method of claim 1, wherein increasing the bonding strength between the membrane layer and the substrate comprises chemically reacting the membrane layer with the substrate.

9. The method of claim 1, wherein increasing the bonding strength between the membrane layer and the substrate comprises inserting an adhesive interlayer between the membrane and the substrate.

10. A structure comprising:
a substrate;
a membrane layer; and
a sacrificial material layer disposed between the substrate and the membrane layer;
wherein a portion of the membrane layer is suspended over an opening in the sacrificial material layer and the substrate, and further wherein a region of the membrane layer around the suspended portion is bonded to a ledge on the substrate with an adhesion strength that is equal to or greater than the intrinsic breaking strength of the membrane layer.

11. The structure of claim 10, wherein the membrane layer is a single-crystalline semiconductor device layer, the sacrificial material layer is a buried oxide layer, and the substrate is a semiconductor handle wafer.

12. The structure of claim 11, wherein the single-crystalline semiconductor device layer comprises single-crystalline silicon and the handle wafer is a silicon wafer.

13. The structure of claim 10, wherein the membrane layer has a thickness in the range from 5 nm to 300 nm.

14. A microelectromechanical device incorporating the structure of claim 10.
